(19) United States
(12) Patent Application Publication
(10) Pub. No.: US 2012/0131403 A1
(43) Pub. Date: May 24, 2012

(54) MULTI-CHIP TEST SYSTEM AND TEST METHOD THEREOF

(75) Inventors: Chih-Jen Chin, Taipei (TW); Lien-Feng Chen, Taipei (TW)

(73) Assignee: INVENTEC CORPORATION, Taipei (TW)

(21) Appl. No.: 13/040,106

(22) Filed: Mar. 3, 2011

(30) Foreign Application Priority Data
Nov. 24, 2010 (TW) 099140662

(51) Int. Cl. G01R 31/3177; G06F 11/25

(52) U.S. Cl. 714/727; 714/E11.155

(57) ABSTRACT

A multi-chip test system and a method thereof utilize a Complex Programmable Logic Device (CPLD) to be connected in series to multiple chips having a Joint Test Action Group (JTAG) interface for function inspection. The test system includes a device to-be-tested and a control device. The device to-be-tested includes multiple chips, a CPLD, and a second JTAG interface. Each of the chips has a first JTAG interface. The CPLD is coupled to the chips through the first JTAG interfaces. The second JTAG interface is connected to the CPLD. The control device is connected to the second JTAG interface and used for sending a switching instruction to the CPLD. In the test method, firstly, a switching instruction is received to select a chip to-be-tested; then, a test signal is sent to the chip to-be-tested according to the chip to-be-tested; and the chip to-be-tested transfers a test result back to a CPLD according to the test signal.

### CROSS-REFERENCE TO RELATED APPLICATIONS

This non-provisional application claims priority under 35 U.S.C. §119(a) on Patent Application No. 099140662 filed in Taiwan, R.O.C. on Nov. 24, 2010, the entire contents of which are hereby incorporated by reference.

### BACKGROUND OF THE INVENTION

1. Field of the Invention

The present invention relates to a multi-chip test system and a method thereof, and more particularly to a test system and a method thereof which utilize a Complex Programmable Logic Device (CPLD) to be connected in series to multiple chips having a Joint Test Action Group (JTAG) interface for inspecting functions of the chips.

2. Related Art

Generally, after a circuit board is manufactured, some flying probe tests are usually performed, so as to ensure that no open/short circuits exist for integrated circuits disposed on the circuit board. The flying probe tests cannot inspect the operation of the integrated circuits on the circuit board, and the inspection of the operation of the integrated circuits often requires cumbersome simulations and tests.

However, with the development of integrated circuit testing, a JTAG interface is disposed for internal testing. A common JTAG test method is to use a boundary scan method for testing by accessing an interface of an integrated circuit. In short, a test signal is input to the integrated circuit. If a signal output by the integrated circuit is an erroneous signal, it can be known that an error occurs in an internal loop of the integrated circuit. The JTAG is also referred to as a standard test access port and boundary scan architecture protocol, which is the IEEE 1149.1 standard certified by the Institute of Electrical and Electronics Engineers (IEEE).

In the design of a current computer main board, test points are reserved for inspection, and bed-of-nails equipment is needed for processing in a test process.

However, chips on the main board are enormous and test specifications for the chips are not uniform, besides the test process is cumbersome and complex, suitable bed-of-nails test equipment needs to be designed, which considerably increases the manufacturing cost.

Therefore, it is an objective of persons in the art to provide a method or means which can reduce the manufacturing cost, reduce the complexity of the test process, and increase the efficiency and speed of inspection.

### SUMMARY OF THE INVENTION

Accordingly, the present invention is a multi-chip test system and a method thereof, which utilize a CPLD to be connected in series with multiple chips having a JTAG interface for inspecting functions of the chips. Therefore, multiple chips are inspected through a single window, so that the design of inspection points for a JTAG interface of each chip is reduced, so as to simplify the difficulty and complexity in a test process, thereby increasing the efficiency and speed of inspection.

The multi-chip test system according to the present invention comprises a device to-be-tested (or called as device-under-test) and a control device. The device to-be-tested comprises multiple chips, a CPLD, and a second JTAG interface. Each of the chips has a first JTAG interface. The CPLD is coupled to the corresponding chips through the first JTAG interfaces. The second JTAG interface is connected to the CPLD. The control device is connected to the second JTAG interface and used for sending a switching instruction to the CPLD.

The switching instruction is transferred to the CPLD through the second JTAG interface, the CPLD selects a corresponding chip according to the switching instruction, and sends a test instruction to inspect the selected chip, and then the CPLD transfers a test result back to the control device.

The multi-chip test method according to the present invention is applied to the multi-chip test system. In the test method, firstly, a switching instruction sent from a CPLD is received, so as to select at least one chip to-be-tested; then, a test signal is sent to the selected chip to-be-tested, and the chip to-be-tested is enabled to generate a test result; and finally, the test result is transferred back to the CPLD.

Therefore, through the above test system and test method, by connecting a CPLD to multiple chips having a JTAG interface, a user can send a switching instruction through a control device, so as to select a chip to-be-tested, and then the CPLD selects a chip according to the switching instruction, and sends a test signal conforming to a corresponding chip test specification. In this way, the design of inspection points for a JTAG interface of each chip is reduced, so as to simplify the difficulty and complexity in a test process, thereby increasing the efficiency and speed of inspection.

### BRIEF DESCRIPTION OF THE DRAWINGS

The present invention will become more fully understood from the detailed description given herein below for illustration only, and thus are not limitative of the present invention, and wherein:

FIG. 1 is a schematic view of a multi-chip test system of the present invention;

FIG. 2 is a schematic view of functional blocks in a CPLD in FIG. 1; and

FIG. 3 is a flow chart of a multi-chip test method of the present invention.

### DETAILED DESCRIPTION OF THE INVENTION

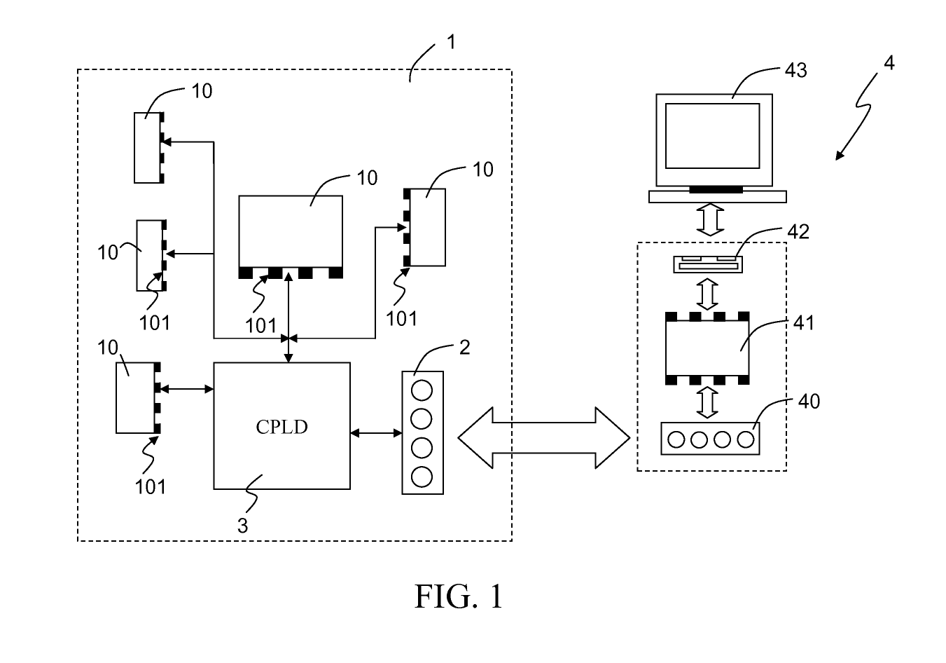

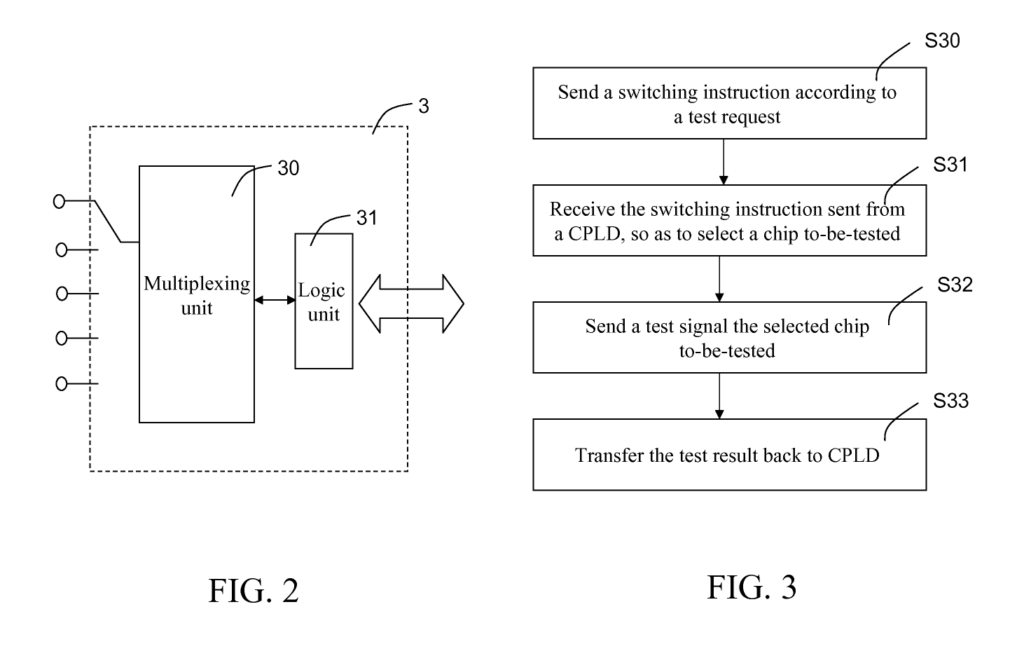

FIG. 1 is a schematic view of a multi-chip test system of the present invention, and FIG. 2 is a schematic view of functional blocks in a CPLD in FIG. 1.

The multi-chip test system of the present invention comprises a device to-be-tested 1 and a control device 4. The device to-be-tested 1 comprises multiple chips 10, a CPLD 3, and a second JTAG interface 2. Each of the chips 10 respectively has a first JTAG interface 101. The CPLD 3 is coupled to the corresponding chips 10 through the first JTAG interfaces 101. The second JTAG interface 2 is connected to the CPLD 3. The control device 4 has a third JTAG interface 40 connected to the second JTAG interface 2. The control device 4 sends a switching instruction to the CPLD 3.

The switching instruction is transferred to the CPLD 3 through the second JTAG interface 2, the CPLD 3 selects a corresponding chip 10 according to the switching instruction and sends at least one test signal to at least one corresponding chip 10, the corresponding chip 10 generates a test result, and the CPLD 3 then transfers the test result back to the control device 4.

In this embodiment, the device to-be-tested 1 may be a computer main board, each of the chips 10 may be a central processing unit, a south-bridge chip or a north-bridge chip, but the present invention is not limited thereto. The CPLD 3 comprises a logic unit 31 and a multiplexing unit 30. The logic unit 31 is connected to the control device 4 and used for receiving the switching instruction, and sending a corresponding test signal according to the switching instruction. The multiplexing unit 30 has a first interface and multiple second interfaces. The first interface is connected to the logic unit 31, each of the second interfaces is connected to the corresponding first JTAG interface 101, and the multiplexing unit 30 establishes a delivery channel with the corresponding chip 10 according to the test signal, in order for the test signal to inspect the chips 10.

The logic unit 31 has function test application software and multiple logic elements. The function test application software is stored in the logic unit 31 in the form of firmware of an embedded system architecture. The function test application software controls the logic elements to generate a test signal according to a chip 10 to-be-tested specified by the switching instruction.

The control device 4 further comprises a universal serial bus interface 42 and a microprocessor 41. The third JTAG interface 40 is connected to the second JTAG interface 2. The universal serial bus interface 42 is connected to an operating device 43, in order for a user to set the switching instruction and receive the test result after the chip 10 is tested through the universal serial bus interface 42. The microprocessor 41 is connected to the third JTAG interface 40 and the universal serial bus interface 42 and used for communicating with the CPLD 3.

It should be noted that, the present invention is also characterized in that, since inspection specifications for the chips 10 may vary with different chip manufacturers, the firmware architecture of the present invention enables the user to easily construct different test environments by updating the function test application software stored in the CPLD 3 through the communication between the second JTAG interface 2 and the third JTAG interface 40, without requiring any additional cost.

FIG. 3 is a flow chart of a multi-chip test method of the present invention. Referring to FIG. 3, the test method at least comprises the following steps.

In Step S31, a switching instruction sent from a CPLD is received, so as to select at least one chip to-be-tested.

In Step S32, a test signal is sent to the selected chip to-be-tested, and the chip to-be-tested is enabled to generate a test result.

In Step S33, the test result is transferred back to CPLD.

Before Step S31, the test method further comprises Step S30, and in Step S30, a control device sends the switching instruction according to a test request.

Based on the above, through the above test system and test method, by connecting a CPLD to multiple chips having a JTAG interface, a user can send a switching instruction through a control device, so as to select a chip to-be-tested, and then the CPLD selects a chip according to the switching instruction, and sends a test signal conforming to a corresponding chip test specification. In this way, the design of inspection points for a JTAG interface of each chip is reduced, so as to simplify the difficulty and complexity in a test process, thereby increasing the efficiency and speed of inspection.

What is claimed is:

1. A multi-chip test system, comprising:
a device to-be-tested, comprising:
multiple chips, each of the chips has a first Joint Test Action Group (JTAG) interface;
a Complex Programmable Logic Device (CPLD), coupled to the chips through the first JTAG interfaces; and
a second JTAG interface, connected to the CPLD; and
a control device, having a third JTAG interface, and connected to the second JTAG interface, wherein the control device sends a switching instruction to the CPLD, the switching instruction is transferred to the CPLD through the second JTAG interface, the CPLD sends at least one test signal to at least one corresponding chip according to the switching instruction, and the corresponding chip generates a test result and transfers the test result back to the control device.

2. The multi-chip test system according to claim 1, wherein the CPLD comprises:
a logic unit, connected to the second JTAG interface, for receiving the switching instruction, and sending the corresponding test signal according to the switching instruction; and
a multiplexing unit, having a first interface and multiple second interfaces, wherein the first interface is connected to the logic unit, each of the second interfaces is connected to the corresponding first JTAG interface, and the multiplexing unit establishes a delivery channel with the corresponding chip according to the test signal, in order for the test signal to inspect the chips.

3. The multi-chip test system according to claim 2, wherein the logic unit has function test application software and multiple logic elements, and the function test application software controls the logic elements according to the switching instruction, so as to generate the test signal.

4. The multi-chip test system according to claim 1, wherein the control device comprises:
an operating device;
a universal serial bus interface, connected to the operating device, wherein the operating device sets the switching instruction and receives the test result through the universal serial bus interface; and
a microprocessor, connected to the third JTAG interface and the universal serial bus interface.

5. A multi-chip test method, comprising:
receiving a switching instruction sent from a Complex Programmable Logic Device (CPLD), so as to select at least one chip to-be-tested;
sending a test signal to the selected chip to-be-tested, and enabling the chip to-be-tested to generate a test result; and
transferring the test result back to the CPLD.

6. The test method according to claim 5, wherein before the step of receiving the switching instruction sent from the CPLD, the test method further comprises:
enabling a control device to send the switching instruction according to a test request.

7. The test method according to claim 5, wherein the switching instruction is sent to the CPLD through a Joint Test Action Group (JTAG) interface.

8. The test method according to claim 5, wherein the test signal is sent to the chip to-be-tested through a JTAG interface.

9. The test method according to claim 5, wherein the test result is transferred back to the CPLD through a JTAG interface.
